(19) United States
(12) Patent Application Publication
(10) Pub. No.: US 2006/0154593 A1
(43) Pub. Date: Jul. 13, 2006

(54) Fan fixation structure for a server

(75) Inventors: Shu-Ju Lin, Taipei (TW); Banks Chen, Taipei (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: Inventec Corporation, Taipei (TW)

(21) Appl. No.: 11/191,388

(22) Filed: Jul. 28, 2005

(30) Foreign Application Priority Data
Dec. 30, 2004 (TW) 093221272

(51) Int. Cl. H05K 5/00

(52) U.S. Cl. 454/184

(57) ABSTRACT

A fan fixation structure for a server is provided, comprising a first scarfing portion disposed on the server, a first connection portion disposed on the server, a second scarfing portion disposed at a rear end of the fan and may be scarfed to the first scarfing portion, a first extension member disposed at a front end of the fan and has a proper elasticity, a second connection portion formed integrally with the first extension member and movable back and forth with the extension member between a first position and a second position and capable of locking with the first connection portion at the first position. As such, a user may rapidly detach or install each fan from or into the server separately without any tool.

### BACKGROUND OF THE INVENTION

1. Field of the Invention

The present invention relates to a heatsink structure for an industrial server, and particularly to a fan fixation structure through which each fan may be easily installed/detached into/from the industrial server separately without any tool.

2. Description of the Related Art

For a mainframe computer or industrial server typically used to process a large amount of data, a central processing unit (CPU) or hard disk thereof may generate a large amount of heat. Once not processed properly, the heat will increase temperature of the CPU or hard disk and the ambient environment, reducing stability and even resulting in the computer or server crash.

Conventionally, a plurality of fans is usually installed within the computer or server to cause air convection to remove the undesirable heat. Since the temperature of the internal components of the computer or server may be efficiently reduced and the cost is acceptable, such heatsink mechanism has been widely employed. Such technology may be seen in, for example, the published patent TW584246.

To facilitate these fans to be installed together and steadily in the computer or server, a heatsink module is generally established and fixed on a supporting frame in the computer or server, which may be seen in the above mentioned patent. However, such fixation has its disadvantage that each fan is required to be fixed on the supporting frame through four holes at its four corners and long screw bolts inserted therein. For example, when a single fan is damaged and required to be replaced, all the fans fixed on the mechanical structure have to be detached at the same time and installed again. Apparently, such fixation mechanism is not convenient to a user.

### SUMMARY OF THE INVENTION

It is, therefore, an object of the present invention to provide a fan fixation structure for a server through which fans are easy to be detached or installed therefrom or thereinto without using tools.

It is another object to provide a fan fixation structure for a server through which each fan may be detached or installed therefrom or thereinto separately without a need of detaching or installing them together.

To achieve the above objects, the fan fixation structure comprises a first scarfing portion disposed at a predetermined portion of the server, a first connection portion disposed at a predetermined portion of the server, a second scarfing portion disposed at a rear end of the fan and may be scarfed to the first scarfing portion, a first extension member disposed at a front end of the fan and has a proper elasticity at a predetermined portion, a second connection portion formed integrally with the first extension member and movable back and forth with the extension member between a first position and a second position and capable of locking with the first connection portion at the first position. As such, a user may rapidly detach or install each fan from or into the server separately without any tool.

To enable persons of the art to fully understand the foregoing object, features and advantages of the present invention, the present invention will be explained below in detail in connection with the preferred embodiments along with the accompanying drawings in an exemplary sense.

### BRIEF DESCRIPTION OF THE DRAWINGS

The invention can be fully understood from the detailed description to the embodiments and the drawings given hereinbelow, and the embodiments and the drawings are not limitative to the right scope of the present invention, and wherein:

FIG. 1 is a perspective view of a fan fixation structure according to a first embodiment of the present invention;

FIG. 2 is an exploded view of the fan fixation structure according to the first embodiment of the present invention;

FIG. 3 is a cross sectional view of the fan fixation structure according to the first embodiment of the present invention;

FIG. 4 is a cross sectional view of the fan fixation structure according to a second embodiment of the present invention;

FIG. 5 is a cross sectional view of the fan fixation structure according to a third embodiment of the present invention; and

FIG. 6 is a cross sectional view of the fan fixation structure according to a fourth embodiment of the present invention.

### DETAILED DESCRIPTION OF THE INVENTION

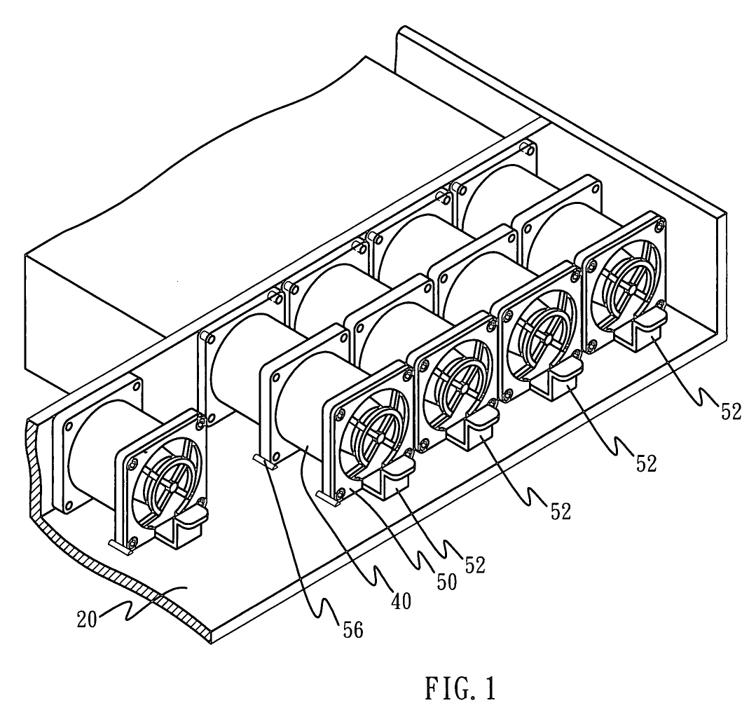

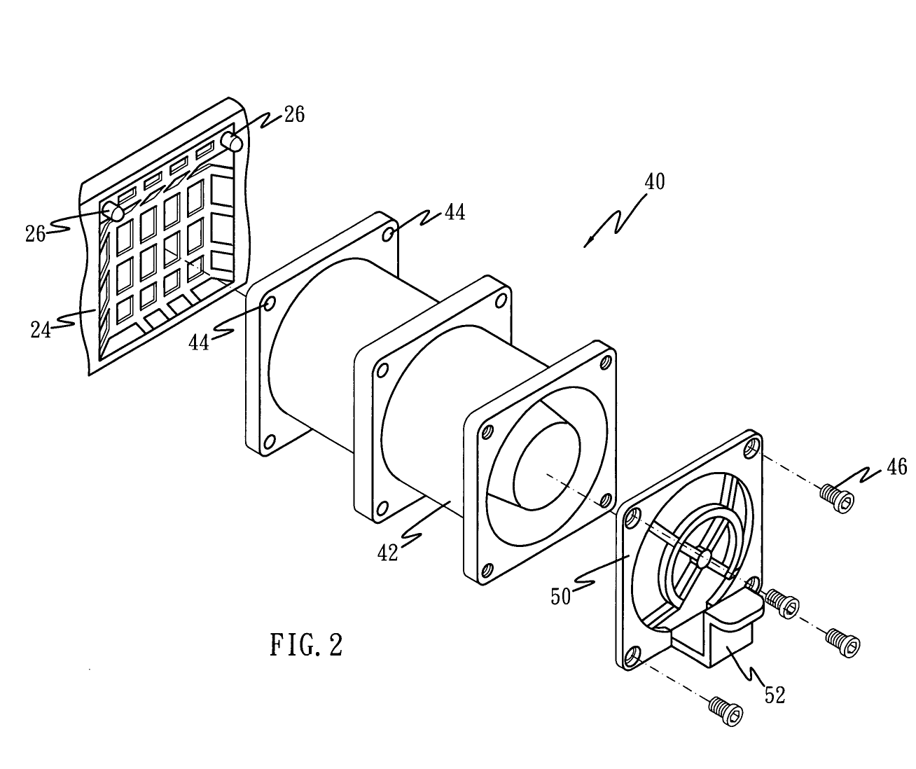

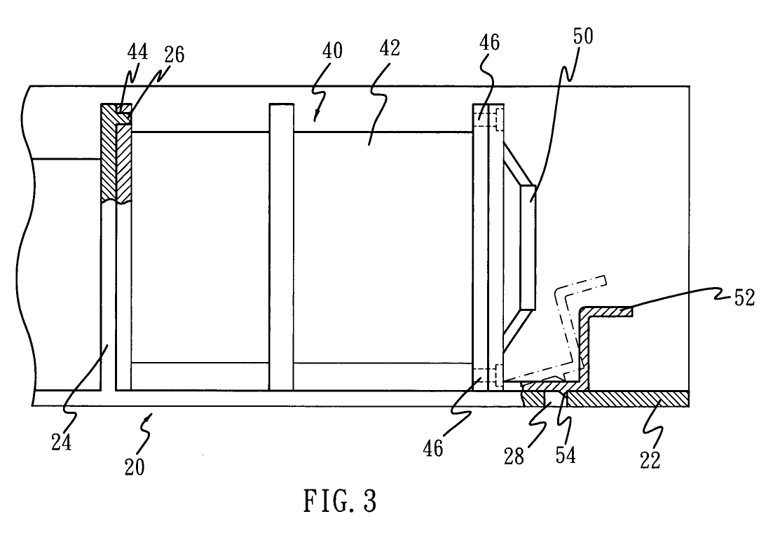

Referring to FIG. 1, FIG. 2 and FIG. 3, a fan fixation structure of a server comprises a supporting frame 20 and a plurality of fans 40 fixed on the supporting frame 20.

As related to the supporting frame 20, a loading portion 22 is provided and the fans 40 are fixed thereon. A vertical wall 24 is provided vertically to the loading portion 22 against which the fans 40 are arranged. A plurality of pairs of first scarfing members 26 are located on an upper end of the vertical wall 24 and each located at a proper distance from another. A plurality of first connection portions 28 is provided and each of which is a through-hole penetrating the loading portion 22 and disposed in front of one of the pairs of the first scarfing portions 26.

Each of the fans 40 is provided with a housing 42 for accommodation of fans and motors (not shown) therein. A pair of second connection portions 44 is disposed on an upper edge of a rear end of the housing 42. Two pairs of short thread bolts 46 are used to fix a safe mask 50 onto a front end of the housing 42 through four comers of the safe mask 50. A first extension member 52 having a crooked shape extends forward and upward and is formed integrally with the safe mask 50. The first extension member 52 has a slightly elasticity and thus may swing back and forth between a first and second positions with respect to a connection position of the safe mask 50 and the first extension member 52. A second connection portion 54 is located at a lower edge as a wedge-shaped protrusion formed integrally with the first extension member 52.

In assembling the fan 40, the second scarfing portions 44 of the fan 40 are aligned to the first scarfing portions 26 so that the first and second scarfing portions 26, 44 may scarf with each other. Next, the housing 42 is placed on an upper side of the loading portion 22 and then the second connection portions 54 are each inserted into a corresponding one of the first connection portions 28. As such, the housing 42 may be kept in a state where a rear end thereof lies against a front end of the vertical wall 24 and placed above the loading portion 22.

When a user desires to remove one of the fans 40, he may push the first extension member 52 from the first position where the first extension member 52 is kept fixed to the second position so that the second connection portion 54 may be separated from the first connection portion 28. At this time, the user may remove the fan 40 in front of the vertical wall 24. Further, since each fan 40 corresponds to a pair of first scarfing portions 26 and a first connection portion 28, the fan 40 is easy to be separately detached or installed without any tool.

Further, a side stopper 56 is integrally formed with the supporting frame 20 and protrudes beyond an upper side of the loading portion 22. A side of the most left one among the fans 40 leans against the side stopper 56 (viewed in the direction shown in FIG. 1) so that the fans 40 may arrange closely in sequence and shake in a less level.

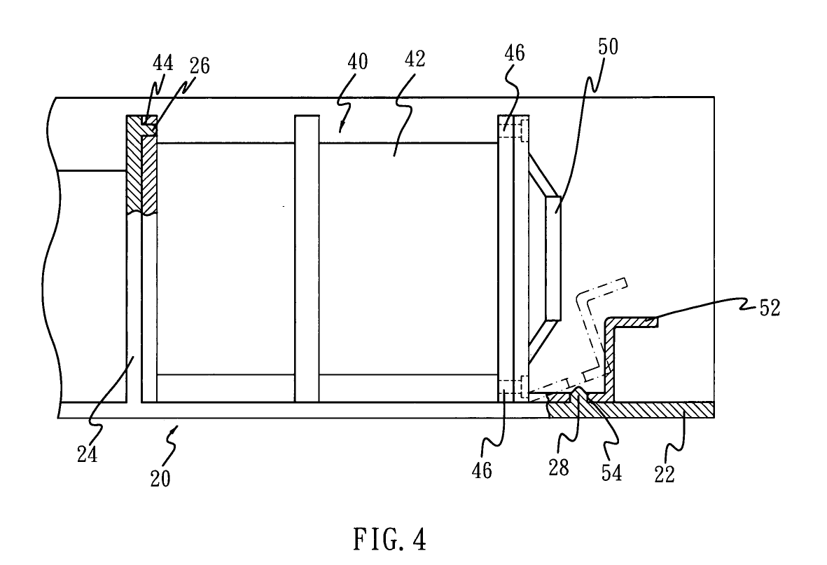

Although the first, second scarfing portions 26, 44, first and second connection portions 28, 54 and side stopper 56 have been disclosed in the above, shape and number of the components 26, 44, 28, 54, 56 may not be limited as the above. Referring to FIG. 4, another embodiment of the fan fixation structure of the present invention is disclosed therein. In this embodiment, the first connection portion 28 is a protrusion formed integrally with the loading portion 22 and the second connection portion 54 is a through-hole integrally with the first extension member 52. This embodiment may not only achieve the same result but also have an identical operating manner as those of the above embodiment.

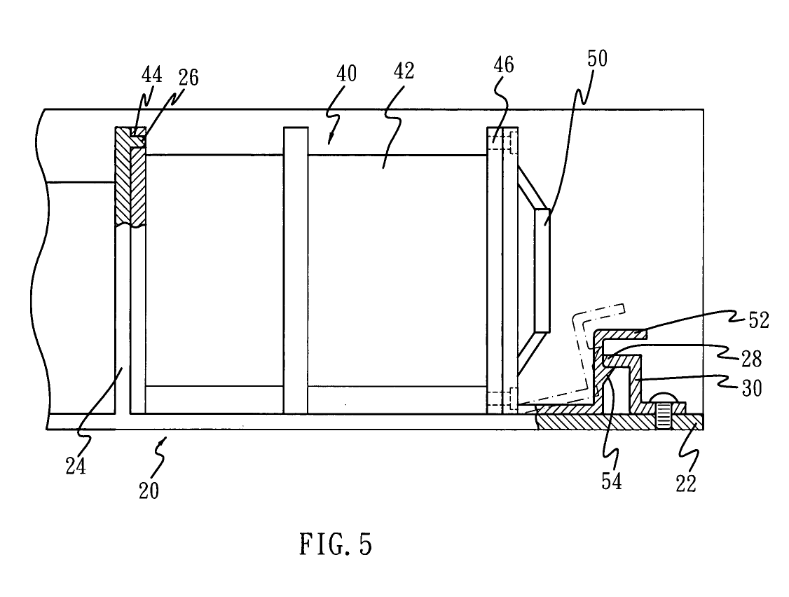

Referring to FIG. 5, yet another embodiment of the fan fixation structure of the present invention is disclosed therein. In this embodiment, scarfing manner and shapes of the first and second scarfing portions 26, 44 are maintained while a stopper 30 is further disposed on the supporting frame 20.

The stopper 30 is fixed on the loading portion 22 and shaped in a crooked form. On its top extension, a first connection portion 28 toward the fans 40 is formed. On the other hand, the second connection portion 54 is a wedge-shaped protrusion protruding from a front side of the first extension member 52.

When the first connection portion 28 leans against the front side of the first extension member 52, the first connection portion 28 is stopped over the second connection portion 54 so that the fan 40 may be steadily fixed on the supporting frame 20. Further, detaching of any of the fans 40 in this embodiment may be achieved by the same operating manner as that of the above embodiment.

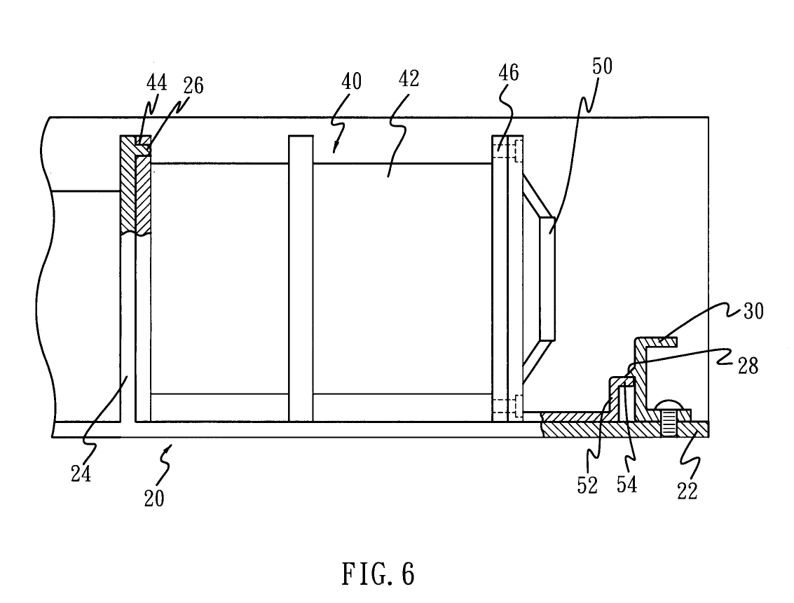

Referring to FIG. 6, the front side of the fan 40 is fixed similarly by pressing the first connection portion 28 disposed on the crooked stopper 30 upon the second connection portion 54 at a distal end of the first extension member 52.

However, since the stopper 30 is provided with slight elasticity so that an upper end thereof may slightly swing with respect to the other end adjacent to a lower end of the loading portion 22 and since the first connection portion 28 protrudes backward and the second connection portion 54 extends forward, the stopper 30 has to be pulled backward when the fan 40 is to be detached. As such, the first connection portion 28 may come off from the state of pressing against the second connection portion 54.

While the preferred embodiments of the invention have been described, it will be apparent to those skilled in the art that various modifications may be made in the embodiments without departing from the spirit of the present invention. Such modifications are all within the scope of the present invention.

What is claimed is:

1. A fan fixation structure for a server, comprising:
at least one pair of first scarfing portions disposed on the server;
a plurality of first connection portion disposed on the server and separated with a proper distance with the first scarfing portion;
a pair of second scarfing portion disposed at a rear end of the fan and scarfed to the first scarfing portion;
a first extension member disposed at a front end of the fan and has a proper elasticity; and
a second connection portion formed integrally with the first extension member and movable back and forth with the extension member between a first position and a second position and capable of locking with the first connection portion at the first position.

2. The fan fixation structure for a server as claimed in claim 1, wherein a safe mask is disposed at a front end of the fan and the first extension member is formed integrally with the safe mask.

3. The fan fixation structure for a server as claimed in claim 1, wherein the first connection portion is a through-hole and the second connection portion is a protrusion scarfable into the through-hole.

4. The fan fixation structure for a server as claimed in claim 1, wherein the first connection portion is a protrusion disposed on the server and the second connection portion is a through-hole disposed on the first extension member and scarfable by the protrusion.

5. The fan fixation structure for a server as claimed in claim 1, wherein the second connection portion is capable of swing back and forth in a predetermined direction with respect to the first extension member.

6. The fan fixation structure for a server as claimed in claim 1, wherein a stopper is provided correspondingly to the front end of the fan, the first connection portion is disposed on the stopper and the second connection portion is a protrusion capable of being stopped by the stopper.

7. The fan fixation structure for a server as claimed in claim 1, wherein the stopper is capable of swing in a predetermined direction thereof to release the second connection portion stopped thereby.

8. The fan fixation structure for a server as claimed in claim 1, wherein the first scarfing portion is a protrusion and the second scarfing portion is a through-hole.

9. The fan fixation structure for a server as claimed in claim 8, wherein the server has a loading portion for supporting the fan and a vertical wall disposed at a predetermined angle with respect to the loading portion for supporting the first scarfing portion thereon.

10. The fan fixation structure for a server as claimed in claim 1, wherein the server has at least a side stopper arranged between the first scarfing portion and the first connection portion and pushing against a protrusion at a lateral side of the fan.
